(19) United States
(12) Patent Application Publication
(10) Pub. No.: US 2026/0191112 A1
(43) Pub. Date: Jul. 2, 2026

(54) THREE-DIMENSIONAL INTEGRATED CIRCUIT FABRICATION USING WAFER-TO-WAFER BONDING

(71) Applicant: HaiSemi Inc., Pheonix, AZ (US)

(72) Inventor: Shengmin WEN, Phoenix, AZ (US)

(21) Appl. No.: 19/421,913

(22) Filed: Dec. 16, 2025

Related U.S. Application Data
(60) Provisional application No. 63/738,946, filed on Dec. 26, 2024.

(51) Int. Cl. H10W 90/28; H10P 52/40; H10P 58/00; H10W 80/00; H10W 90/00

(52) U.S. Cl. CPC H10W 90/28; H10P 52/402; H10P 58/20; H10W 80/312; H10W 80/327; H10W 90/722; H10W 90/792

(57) ABSTRACT

Embodiments relate to a three-dimensional integrated circuit (3D IC) fabrication process involving wafer-to-wafer bonding of a first wafer to a second wafer. The process includes partially cutting trenches in the second wafer's streets, aligning interconnects between the two wafers, and coupling them to form a wafer stack. The second wafer is then thinned to expose the partially cut trenches, and materials between the second wafer's dies are removed to expose die pads on the first wafer for external connection, enabling the creation of a 3D IC with improved connectivity and functionality.

### CROSS-REFERENCE TO RELATED APPLICATIONS

This application claims priority to U.S. patent application Ser. No. 63/738,946, filed on Dec. 26, 2024, which is incorporated by reference herein in its entirety.

### TECHNICAL FIELD

The present disclosure relates to integrated circuits (ICs), and more specifically to manufacturing of stacked three-dimensional integrated circuits (3D ICs).

### BACKGROUND

In recent years, the semiconductor industry has experienced rapid growth due to continuous improvement in integration density of various electronic components such as transistors, diodes, resistors, and capacitors. Such improvement in integration density is mostly attributed to successive reductions in minimum feature sizes, which allows more components to be integrated into a given area.

These smaller electronic components also require smaller packages that occupy less area than previous packages. Exemplary types of packages for semiconductors include quad flat pack (QFP), pin grid array (PGA), ball grid array (BGA), flip chips (FC), three dimensional integrated circuits (3D ICs), wafer level packages (WLPs), and package on package (PoP) devices. Some 3D ICs are prepared by placing chips over chips on a semiconductor wafer level. 3D ICs provide improved integration density and other advantages, such as faster speeds and higher bandwidth, because of the decreased length of interconnects between the stacked chips. However, there are quite a few challenges to be handled for the technology of 3D ICs. For example, if a 3D IC involves two different die sizes a die-to-die integration or die-to-wafer integration is the method of choice and the state of art process. Such process has low throughput and high cost. Another example is that in most cases a through silicon vias (TSVs) process is involved, which raises cost and reduces electrical performance.

### SUMMARY

Embodiments relate to fabrication three-dimensional integrated circuit (3D IC). A first wafer having a first plurality of dies is prepared. Trenches in a second street of a second wafer having a second plurality of dies are partially cut. A first plurality of interconnects on the first plurality of dies are aligned with a second plurality of interconnects on the second plurality of dies. The second wafer is coupled with the first wafer to create a wafer stack with the first plurality of interconnects and the second plurality of interconnects aligned. The second wafer is thinned to expose the partially cut trenches. Materials of the second street between the second plurality of dies of the second wafer are removed to expose a plurality of die pads on the first plurality of dies of the first wafer for external connection.

In one or more embodiments, the first plurality dies are of a first die size and the second plurality of dies are of a second die size that is smaller than the first die size, and the first wafer has first streets and the second wafer has second streets that are wider than the first streets.

In one or more embodiments, the first wafer and the second wafer are of the same size.

In one or more embodiments, chemical mechanical planarization (CMP) is performed on the first and second wafers for coupling.

In one or more embodiments, activating at least a surface of the first wafer or a second wafer is performed after performing the CMP on the first and second wafers and before coupling.

In one or more embodiments, the coupling of the first wafer and the second wafer includes a face-to-face coupling.

In one or more embodiments, the first plurality of interconnects of the first dies and the second plurality of interconnects of the second dies include copper (Cu) pads.

In one or more embodiments, the first plurality of interconnects and the second plurality of interconnects further include dielectric material surrounding the Cu pads.

In one or more embodiments, the dielectric material includes silicon dioxide.

Embodiments also relate to a three-dimensional integrated circuit (3D IC) structure that includes a first IC chip and a second IC chip. The first IC chip includes a first bonding layer that includes first pad in a first dielectric area. The second IC chip includes a second bonding layer that includes a second pad in a second dielectric area. The second pad is bonded to the first pad, and the second dielectric area is bonded to the first dielectric area to form a hybrid bonding structure.

Embodiment also relates to a three-dimensional integrated circuit (3D IC) structure that includes a first IC chip including a first bonding layer including a first pad and a second IC chip including a second bonding structure including a copper (Cu) pillar bump. The first pad is bonded to the copper pillar bump to form a copper (Cu) pillar flip chip structure.

### BRIEF DESCRIPTION OF THE DRAWINGS

FIG. 1A is a perspective view of an example finished three-dimensional integrated circuit (3D IC) wafer.

FIG. 1B is a perspective view of an individual 3D IC die after singulation, according to an example.

FIG. 1C is a top-down view illustrating an individual 3D IC with more details of the interconnecting relationship between the two dies, according to an example.

FIG. 2 is a flow chart illustrating an exemplary process for construction of a 3D IC, according to one embodiment.

FIG. 3A is a top-down view illustrating a first semiconductor wafer according to one embodiment.

FIG. 3B is a cross-sectional view illustrating a die from a first semiconductor wafer, according to one embodiment.

FIG. 4A is a top-down view illustrating a second semiconductor wafer according to one embodiment.

FIG. 4B is a cross-sectional view illustrating a die from a second semiconductor wafer, according to one embodiment.

FIG. 5A is a top-down view illustrating streets of a second semiconductor wafer, according to one embodiment.

FIG. 5B a partial cross-sectional view illustrating a street between two dies from a second semiconductor wafer, according to one embodiment.

FIG. 6A is a top-down view illustrating the partial-cut trenches in each second street of a second semiconductor wafer, according to one embodiment.

FIG. 6B is a partial cross-sectional view illustrating the depth of trenches in streets of a second semiconductor wafer, according to one embodiment.

FIG. 7A is a top-down view illustrating a bonded wafer after exemplary face-to-face wafer bonding, according to one embodiment.

FIG. 7B is a partial cross-sectional view across two dies illustrating the formation of the 3DIC with interconnected dies, according to one embodiment.

FIG. 8A is a top-down view illustrating the exposure of partial-cut trenches after thinning of the second semiconductor wafer, according to one embodiment.

FIG. 8B is a partial cross-sectional view across one die illustrating the partial-cut trenches being exposed after thinning, according to one embodiment.

FIG. 9A is a top-down view illustrating the 3DIC wafer after cleaning the second street materials of the second semiconductor wafer, according to one embodiment.

FIG. 9B is a partial cross-sectional view illustrating two 3D IC dies of the finished 3D IC wafer after cleaning the second street materials of the second semiconductor wafer, according to one embodiment.

The figures depict embodiments of the present disclosure for purposes of illustration only.

### DETAILED DESCRIPTION

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments. In the drawings, reference numerals in the drawings denote elements.

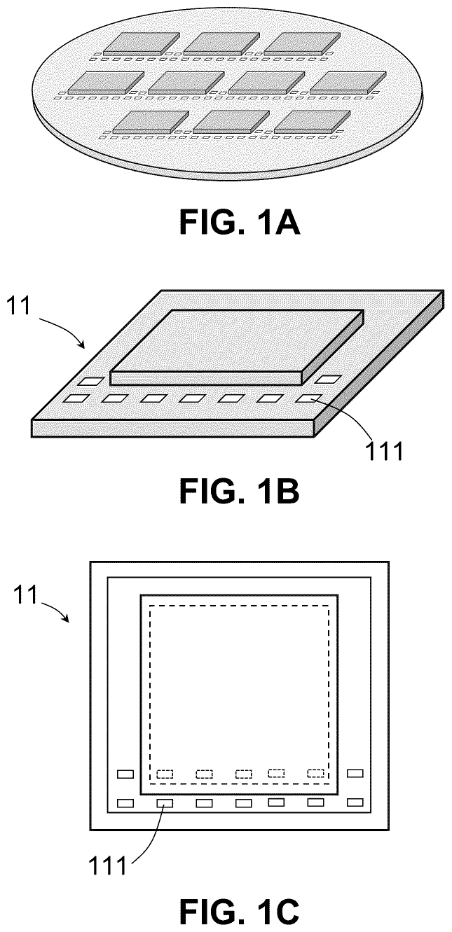

FIGS. 1A through 1C are drawings showing the example constructed 3D IC wafer and dies. FIG. 1A is a perspective view of a finished 3D IC wafer. FIG. 1B is an exemplary 3D IC die 51, where external connecting pads 511 are for wire bond connection or for bumping connection in a semiconductor package.

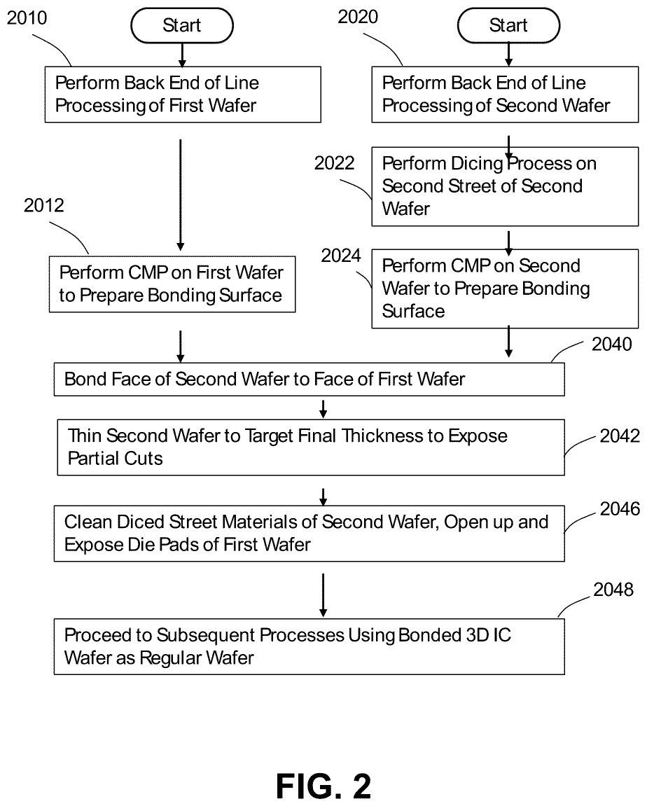

FIG. 2 is a flow chart illustrating an exemplary process for construction of a 3D IC wafer, according to one embodiment. A 3D IC includes two or more dies. Each die of the 3D IC is manufactured on a separate wafer. Back end of line (BEOL) processing is performed 2010 along with forming a set of interconnecting Cu die pads, a set of external connecting die pads, and dielectric materials around these die pads in the first wafer. Chemical mechanical planarization (CMP) processing 2012 is performed on the first wafer to prepare a flat and clean surface for bonding. For hybrid bonding, a surface activation process may be performed on the surface of the first wafer after the CMP processing.

Back end of line (BEOL) processing is performed 2020 on the second wafer, forming interconnecting Cu die pads and dielectric materials. In one or more embodiments, the die size of the second wafer is smaller than the die size of the first wafer. The second street width of the second wafer may be larger than the first street width of the first wafer. Dicing process is performed 2022 on each second street of the second wafer to form a plurality of partial-cut trenches. The trench depth may not extend the full thickness of the second wafer. Chemical mechanical planarization (CMP) processing is performed 2024 on the second wafer to prepare a very flat and clean surface for bonding. For hybrid bonding, a surface activation process may be performed on the surface of the second wafer after the CMP processing.

Then, the second wafer and the first wafer are bonded 2040 together in a face-to-face configuration through a hybrid bonding process. It is noted that several other bonding methods may also be used, such as copper (Cu) pillar bump plus mass reflow plus underfill process, or Cu pillar bump plus thermal compression bonding process. After this hybrid bonding process, the interconnecting Cu die pads of the second wafer are bonded to the interconnecting Cu die pads of the first wafer, forming solid Cu metal connection, and the interconnection dielectric areas of these two wafers are bonded to each other, adding the bonding strength between these two wafers.

The second wafer is thinned 2042 from the back surface all the way until the partial cuts are exposed. After the partial cuts at the second street of the second wafer are exposed, the portion of the second street of the second wafer between the partial-cut trenches becomes loose and can be easily removed and cleaned 2046. This step opens the set of external connecting die pads of the first wafer, and a 3D IC wafer is fabricated. Then 3D IC wafer proceeds 2048 to subsequent processes as a regular wafer. Such subsequent processes include, among others, bumping, wire bonding, thinning, and dicing.

The processes as illustrated in FIG. 2 are merely illustrative. Additional steps may be performed and the sequence of steps may be modified.

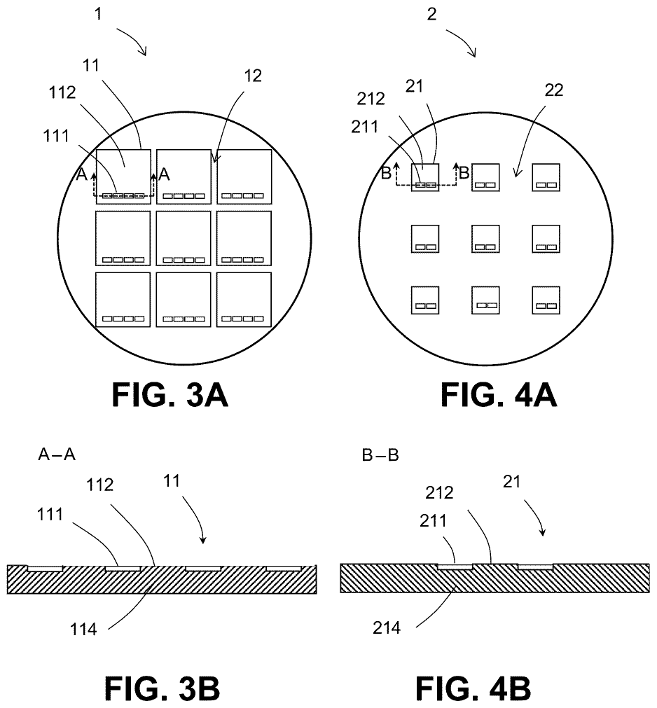

FIGS. 3A through 4B are top-down views and cross-sectional views of two wafers having different die sizes, according to one embodiment. Wafer to wafer bonding of these different dies as described above allows 3D IC fabrication.

FIG. 3A is a top-down view illustrating first wafer 1 according to one embodiment. First wafer 1 includes a plurality of dies 11, having a first bonding layer. The first bonding layer includes dielectric area 112, a plurality of pads 111 deposited thereon for internal and external connecting, and first streets 12 that separates the dies 11.

FIG. 3B is a cross-sectional view taken along line A-A of FIG. 3A, according to one embodiment. First wafer 1 includes a first bonding layer on a substrate portion 114, having internal and external connecting pads deposited on the bonding layer. First wafer 1 may also include various film layers (not shown) deposited on either side of first wafer 1.

FIG. 4A is a top-down view illustrating second wafer 2 according to one embodiment. Second wafer 2 includes dies 21, have a second bonding layer comprising dielectric area 212, a plurality of pads 211 deposited thereon for internal connecting, and second streets 22 that separate the dies 21. It is noted that the size of die 21 of second wafer 2 is different from that of die 11 of first wafer 1, and second streets 22 of wafer 2 are wider than those of first wafer 1.

FIG. 4B is a cross-sectional view taken along line B-B of FIG. 4A, according to one embodiment. Second wafer 2 includes a second bonding layer portion on a substrate portion 214, having internal connecting pads deposited on the bonding layer. Second wafer 2 may also include various film layers (not shown) deposited on either side of second wafer 2.

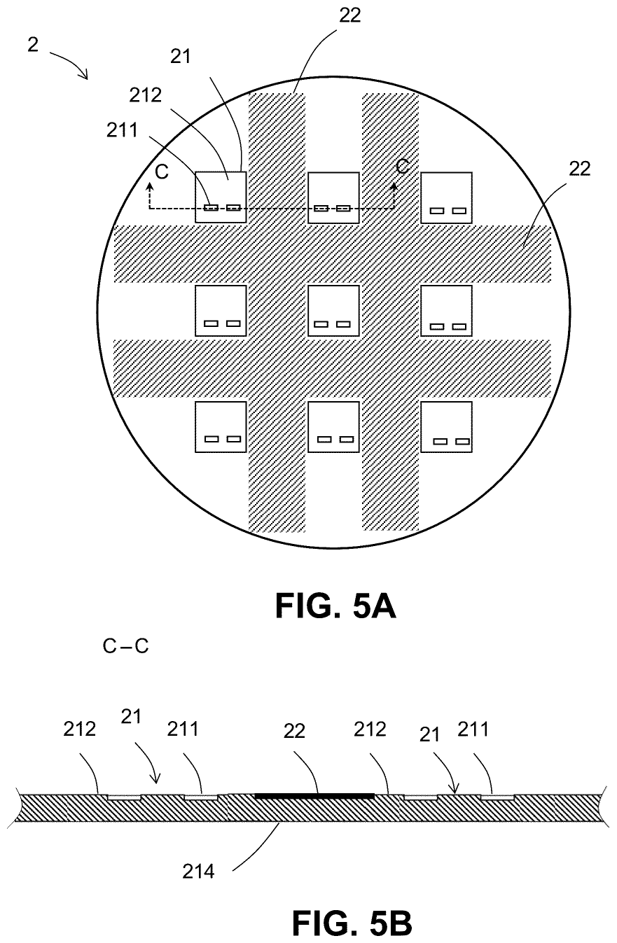

FIGS. 5A and 5B are more detailed drawings showing second wafer 2 of FIG. 4A, according to one embodiment. FIG. 5A is a top-down view illustrating second streets 22, an area that is dissimilar to that of dielectric area 212 and die pads 211. It is noted that during a wafer to wafer bonding process, this area 22 will not establish bonding to the overlapping area of first wafer 1. FIG. 5B is a cross-sectional view taken along line C-C, illustrating two neighboring dies 21 of second wafer 2 that include second streets 22 between these two neighboring dies. As shown, materials of the top levels of second street 22 are dissimilar to dielectric area 212 and die pads 211.

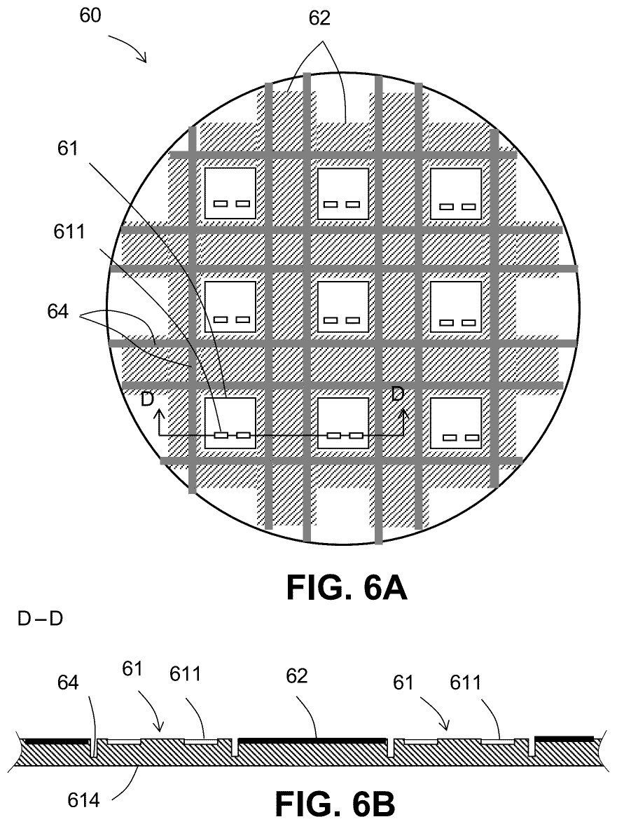

FIG. 6A is a diagram illustrating a top-down view of prepared wafer 60, according to one embodiment. A plurality of trenches 64 are made with a dicing process in the second streets 62. Some or all of these trenches 64 are made as close as 15um to the die edge of die 61.

FIG. 6B is a partial cross-sectional view taken along line D-D of FIG. 6A, according to one embodiment. Wafer 60 includes the second streets 62. The trenches 64 are cut partially without extending through the entire thickness of the wafer 60. The depth of the trenches 64 is defined such that these trenches 64 are exposed in the following back side grind thinning steps of thinning from the substrate side 614. In general, the depth of these trenches 64 may be as low as 30 μm more than the desired final thickness of die 61.

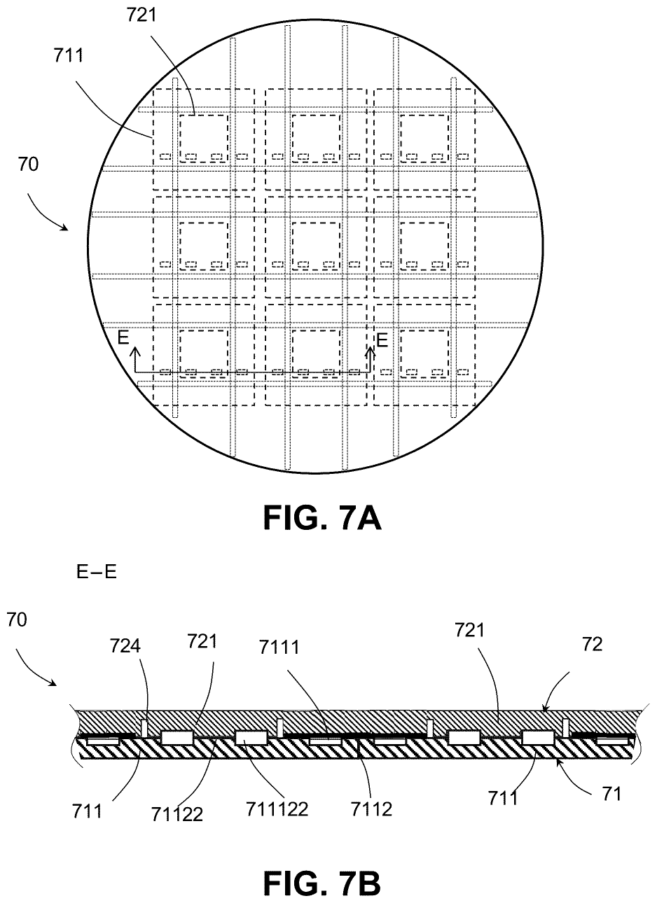

FIG. 7A is a top-down view illustrating a bonded 3D IC wafer after exemplary wafer-to-wafer bonding, according to one embodiment. A second wafer 72 (not shown) and a first wafer 71 (not shown) are bonded with a face-to-face configuration with a wafer-to-wafer hybrid bonding process to form a single bonded wafer 70. The dies 721 of a second wafer 72 and the dies 711 of a first wafer 71 are aligned and bonded between their interconnecting pads and dielectric surface bonding materials, respectively.

FIG. 7B is a partial cross-sectional view taken along line E-E of FIG. 7A, according to one embodiment. The bonded wafer 70 includes the second street 7212 of the wafer 72 between the two dies 721. The dies 721 of a second wafer 72 and the dies 711 of a first wafer 71 overlap interconnect pads as shown in FIG. 7B. That is, the pattern, size and pitch of the interconnecting pads of the dies 721 match the pattern, size and pitch of those corresponding interconnecting pads of the dies 711. Interconnecting pads 7211 (not shown) on dies 721 are arranged to contact the corresponding interconnecting pads 7111 on dies 711, forming metal joints 711122. The dielectric bonding area (not shown) of dies 721 is bonded the dielectric bonding area 7112 to form bonding area 71122. The external contacting pads 7111 of dies 711 face and overlap the second street 7212 of dies 721 and are not bonded together. The first street 7112 between the dies 711 of wafer are also not bonded to the second street 7212 between the dies 721 of wafer 72.

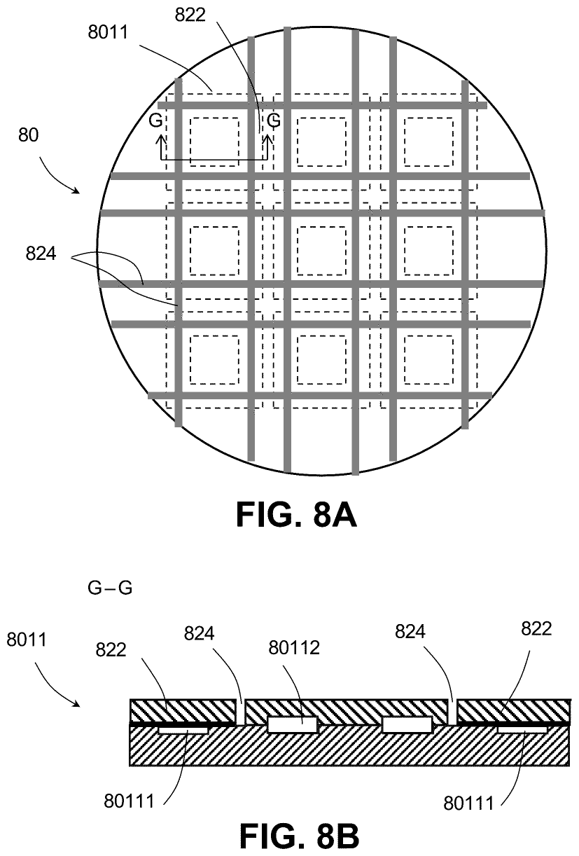

FIG. 8A is a diagram illustrating a top-down view of a 3D IC wafer 80 after exemplary back side thinning to a second wafer, for example, wafer 72 of FIG. 7B, exposing the partial-cut trenches in the second street, according to one embodiment.

FIG. 8B is a cross-sectional view taken along line G-G of FIG. 8A, according to one embodiment. Partial-cut trenches 824 are now exposed and open, leaving materials of the second street 822 without support and ready to be removed and cleaned.

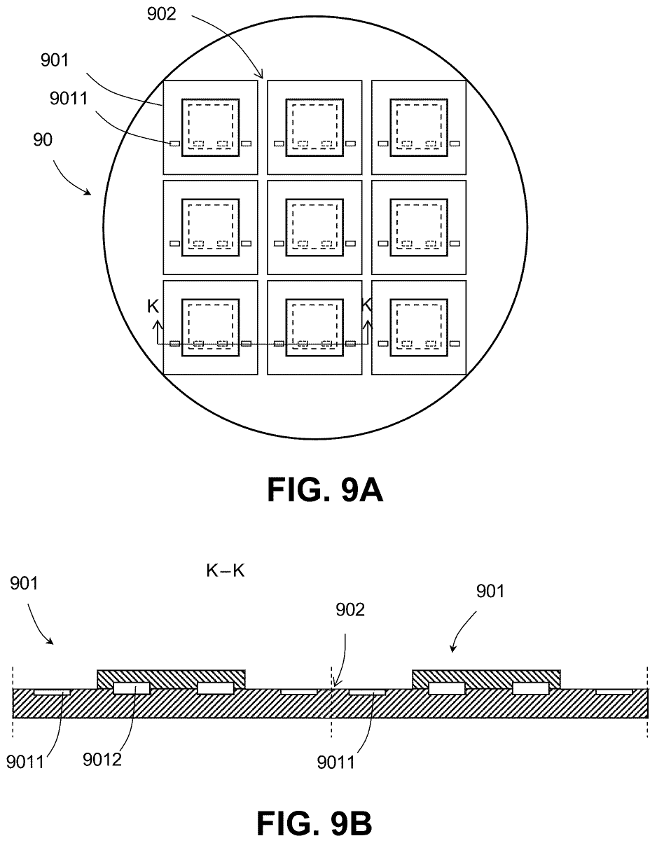

FIG. 9A is a diagram illustrating a top-down view of a 3D IC wafer 90 after exemplary second street materials, e.g., 822 of FIG. 8B, removal and cleaning process according to one embodiment. 3D IC dies 901 are fabricated and their external connecting pads 9011 are exposed, ready for following wafer or die preparation steps—wire bonding or flip chip bonding. It is noted that the 3D IC 901 connects externally without through silicon vias (TSVs).

FIG. 9B is a cross-sectional view taken along line K-K of FIG. 9A, according to one embodiment. The 3D IC is fabricated by joining two dies via their interconnect die pads to establish connection 9012. The external connecting pads 9011 are ready for external connections without TSVs. The 3D IC dies maybe diced along the first street 902, which may be as little as 20 μm in width.

Advantages of fabricating 3D IC through bonding of wafers of dissimilar size dies as described above offers, among others, high throughput, less restriction of process environment, and low cost. The method may obviate TSV construction, which may provide additional cost and performance improvement. Additionally, the example wafer-to-wafer processing may include wafers manufactured at different locations with different technologies and processes, provide supply chain flexibility and time to market.

Upon reading this disclosure, those of skill in the art will appreciate still additional alternative ways of fabricating three-dimensional integrated circuits. Thus, while particular embodiments and applications have been illustrated and described, it is to be understood that the invention is not limited to the precise construction and components disclosed herein and that various modifications, changes and variations which will be apparent to those skilled in the art may be made in the arrangement, operation and details of the method and apparatus disclosed herein without departing from the spirit and scope of the present disclosure.

What is claimed is:

1. A method of fabrication three-dimensional integrated circuit (3D IC), comprising:
preparing a first wafer having a first plurality of dies:
partially cutting trenches in a second street of a second wafer having a second plurality of dies;
aligning a first plurality of interconnects on the first plurality of dies with a second plurality of interconnects on the second plurality of dies;
coupling the second wafer with the first wafer to create a wafer stack with the first plurality of interconnects and the second plurality of interconnects aligned;
thinning the second wafer to expose the partially cut trenches; and
removing materials of the second street between the second plurality of dies of the second wafer to expose a plurality of die pads on the first plurality of dies of the first wafer for external connection.

2. The method of claim 1, wherein the first plurality dies are of a first die size and the second plurality of dies are of a second die size smaller than the first die size, and wherein the first wafer has first streets and the second wafer has second streets that are wider than the first streets.

3. The method of claim 1, wherein the first wafer and the second wafer are a same size.

4. The method of claim 1, further comprising:
performing chemical mechanical planarization (CMP) on the first and second wafers for coupling.

5. The method of claim 4, further comprising activating at least a surface of the first wafer or a second wafer after performing the CMP on the first and second wafers and before coupling.

6. The method of claim 1, wherein the coupling of the first wafer and the second wafer comprises a face-to-face coupling.

7. The method of claim 1, wherein the first plurality of interconnects of the first dies and the second plurality of interconnects of the second dies comprise copper (Cu) pads.

8. The method of claim 7, wherein the first plurality of interconnects and the second plurality of interconnects further comprise dielectric material surrounding the Cu pads.

9. The method of claim 8, wherein the dielectric material comprises silicon dioxide.

10. A three-dimensional integrated circuit (3D IC) structure, comprising:
a first IC chip comprising a first bonding layer comprising a first pad in a first dielectric area; and
a second IC chip comprising a second bonding layer comprising a second pad in a second dielectric area,
wherein the second pad is bonded to the first pad, and the second dielectric area is bonded to the first dielectric area to form a hybrid bonding structure.

11. A three-dimensional integrated circuit (3D IC) structure, comprising:
a first IC chip comprising a first bonding layer comprising a first pad; and
a second IC chip comprising a second bonding structure comprising a copper (Cu) pillar bump, the first pad bonded to the copper pillar bump to form a copper (Cu) pillar flip chip structure.
